(19) United States
(12) Patent Application Publication
(10) Pub. No.: US 2006/0035491 A1
(43) Pub. Date: Feb. 16, 2006

(54) Geared motor and method for assembling the geared motor

(76) Inventors: Laurent Robin, Ouzouer-Le-Marche (FR); Mickael Lebourgeois, Auvilliers En Gatinais (FR); Marie-Pierre Bena, Cerdon Du Loiret (FR)

Correspondence Address: CARLSON, GASKEY & OLDS, P.C., 400 WEST MAPLE ROAD, SUITE 350, BIRMINGHAM, MI, 48009, US

(21) Appl. No.: 11/200,538

(22) Filed: Aug. 9, 2005

(30) Foreign Application Priority Data
Aug. 10, 2004 (FR) 04 08 793

(51) Int. Cl. H05K 1/00

(52) U.S. Cl. 439/76.1

(57) ABSTRACT

A geared motor used for operating a vehicle window regulator includes a housing and a connector receptacle capable of receiving a control connector for the geared motor. The connector receptacle is integrated into and projects from the housing. A printed circuit board with an electronic control unit for the geared motor is within the housing and extends in a direction of the rotor. Pins are electrically connected to the printed circuit board and are capable of being connected directly to the control connector for the geared motor.

### REFERENCE TO RELATED APPLICATIONS

This application claims priority to French Patent Application FR 04 08 793 filed on Aug. 10, 2004.

### BACKGROUND OF THE INVENTION

The present invention relates generally to a geared motor and to a method for assembling a geared motor.

A mechanism for operating an openable member of a vehicle, such as a vehicle window regulator, can be electrically driven and include a geared motor. The geared motor is powered via a connector attached to an end of a branch of a wiring harness. Because the connectors have different shapes depending on the vehicle manufacturer, an adapter is required to provide the mechanical linkage between the various possible connectors and the geared motor. The use of an adaptor incurs additional production costs. There is therefore a need for a less expensive geared motor.

### SUMMARY OF THE INVENTION

The invention provides a geared motor including a motor with a rotor and a stator, a housing fixed to the motor and a connector receptacle integrated into and projecting from the housing and capable of directly receiving a connector for controlling the geared motor. The geared motor includes a printed circuit board for controlling the operation of the geared motor, and the printed circuit board is within the housing and extends in the direction of an axis of the rotor. Conducting pins are connected to the printed circuit board and capable of being connected directly to the control connector for the geared motor.

Preferably, the connector receptacle includes one or more elements for securing the control connector. Preferably, the pins are attached to the printed circuit board, and one free end of the pins are at an upper portion of the connector receptacle. Preferably, the housing includes a motor-attachment interface with an opening for the rotor of the motor to pass through. The opening terminates at an upper portion of the connector receptacle in the direction in which the rotor passes through. Preferably, a distance between the axis of the rotor and the top of the housing is greater than a distance between the axis of the rotor and the top of the pins. Preferably, the pins immobilize the printed circuit board relative to the housing. Preferably, the pins include a pin carrier for attachment to the housing.

The invention also provides a method for assembling the geared motor described above including the steps of introducing a printed circuit board into a housing, introducing pins through an opening of a connector receptacle, and placing the pins in contact with the printed circuit board. Preferably, the pins include a pin carrier, and the method also includes a step of attaching the pin carrier to the housing.

The invention also relates to a method for assembling a variant of the geared motor described above. The method includes the steps of securing pins to a printed circuit board, introducing the printed circuit board through a opening of a housing in a direction of an axis of the rotor. Preferably, the pins extend in a direction perpendicular to the direction of introduction of the printed circuit board.

Preferably, the housing includes a motor-attachment interface with an opening for the rotor of the motor to pass through. The printed circuit board is introduced in the direction in which the rotor passes through the housing.

Other characteristics and advantages of the invention will become apparent when reading the following detailed description of embodiments of the invention, given by way of example only and with reference to the drawings.

### BRIEF DESCRIPTION OF THE DRAWINGS

FIG. 1 shows a geared motor according to one embodiment;

FIG. 2 is a detail view of FIG. 1; and

FIG. 3 shows a geared motor according to another embodiment.

### DETAILED DESCRIPTION OF PREFERRED EMBODIMENTS

The invention provides a geared motor including a housing and a connector receptacle capable of being directly attached to a control connector for the geared motor. The connector receptacle projects from the housing. Moreover, the geared motor includes conducting pins which can be directly connected to the control connector. Thus, the connector receptacle and the pins allow a control connector to be integrated into the geared motor without the intermediary of an adaptor. This reduces the number of parts and thus lowers the production costs of the geared motor.

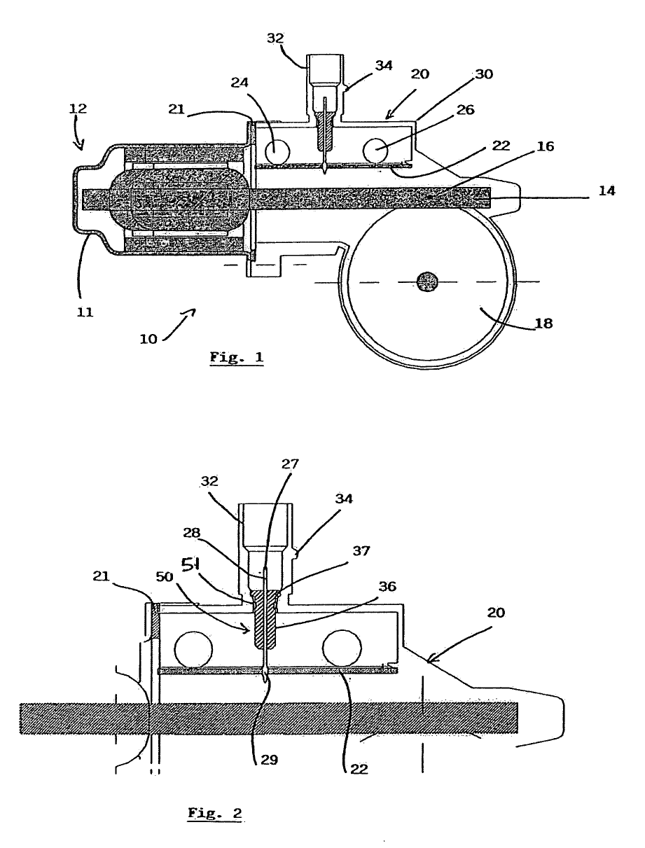

FIG. 1 shows a geared motor 10 according to one embodiment. The geared motor 10 includes a stator 11, a housing 20 and a rotor 14. The stator 11 and the rotor 14 assembly forms part of a motor 12. The housing 20 can include a member forming an interface 21 which seals the motor 12. The rotor 14 in turn drives a reduction gear composed of a worm screw 16 on the rotor 14 and a cog wheel 18 driven by the worm screw 16. The reduction gear is housed in the housing 20.

The geared motor 10 also includes a printed circuit board (PCB) 22 with an electronic control unit (ECU) for controlling the operation of the geared motor 10. In particular, the printed circuit board 22 controls the start-up of the motor 12, reversing its direction of rotation or stopping it. The printed circuit board 22 is composed of a printed circuit. Two components 24 and 26 are shown by way of example. The printed circuit board 22 is inside the housing 20, allowing the housing 20 of the geared motor 10 to be more compact, thus reducing the overall dimensions of the geared motor 10. Moreover, placing the printed circuit board 22 inside the geared motor 10 avoids the need to provide a means of accommodating the printed circuit board 22 on the outside of the housing 20, which would involve additional production costs. The housing 20 can be made slightly larger, namely to 30 in FIG. 1, in order to contain the electronic components of the printed circuit board 22. Moreover, the printed circuit board 22 can extend substantially in the direction of the axis of the rotor 14 (along the major axis of the printed circuit board 22) inside the housing 20, partially penetrating the stator 11 if necessary. This is advantageous when assembling the geared motor 10 because the rotor 14 and the printed circuit board 22 can be inserted along the same axis.

The geared motor 10 also includes a connector receptacle 32. The connector receptacle 32 is shown in FIG. 2, a detail of FIG. 1. The connector receptacle 32 allows a geared motor control connector, not shown, to be attached to the geared motor 10. The connector is at the end of a branch of the vehicle's wiring harness and is connected to the geared motor 10 via the connector receptacle 32. The connector receptacle 32 projects from the housing 20, enabling it to be attached directly to the connector. The connector can be connected directly to the connector receptacle 32 as there is no intermediate part between the connector receptacle 32 and the connector, reducing the production costs of the geared motor 10. The connector receptacle 32 includes walls forming, for example, a well having an approximately rectangular section when viewed in cross-section to the plane of FIG. 1. The connector receptacle 32 opens at its base into the housing 20. By way of example, the connector receptacle 32 projects outwards by 26.35 mm.

The connector receptacle 32 is integral with or is integrated into the housing 20, allowing the connector receptacle 32 and the housing 20 to be produced in the same operation, for example a molding operation, and therefore reducing the production costs of the connector receptacle 32 Oust one production process is needed instead of two in the case of an adapter being present).

Advantageously, the connector receptacle 32 includes one or more attachment elements 34 for securing the control connector. The attachment element 34 immobilizes the connector on the connector receptacle 32. The attachment element 34 can be integral with the connector receptacle 32, facilitating the production of the attachment element 34. The attachment element 34 is, for example, a protuberance cooperating with a cavity in the connector. The attachment element 34 is, for example, on a wall of the connector receptacle 32 along the longitudinal axis of the geared motor 10.

The pins 28 include a pin carrier 50 for attachment to the housing 20. In FIGS. 1 and 2, only one row of 6 to 10 pins 28 is shown, but the geared motor 10 can include two or more rows. The pins 28 are conducting and are electrically connected to the printed circuit board 22. The pins 28 provide the power supply or drive the ECU printed circuit board 22. As can be seen more clearly in FIG. 2, one end 29 of the pins 28 can be inserted into a hole in the printed circuit board 22 to establish contact with printed lines on the printed circuit board 22. The end 29 can be pointed, facilitating its insertion into the printed circuit board 22. The pins 28 are also adapted to be connected directly to the control connector of the geared motor 10.

Another operational end 27 of the pins 28 can be in contact with the connector without an intermediate part, such as an adapter. The pins 28 extend from the printed circuit board 22 into the upper portion of connector receptacle 32. As the connector receptacle 32 is raised or elevated, the pins 28 are longer than standard pins. In FIG. 2, the end 27 of the pins 28 protrudes beyond the cover of the housing 20 and extends into the connector receptacle 32. For this purpose, the pins 28 are longer than standard pins. For example, the pins are 30.25 mm long.

Advantageously, the pins 28, after insertion, immobilize (substantially along the axis of the rotor 14) the printed circuit board 22 in translation relative to the housing 20. The printed circuit board 22 can be held by the housing 20 in a direction perpendicular to the plane of FIG. 2, for example, by slots or grooves along the internal wall of the housing 20. The immobilization of the printed circuit board 22 relative to the housing 20 in the direction of the rotor 14 is achieved by inserting the end 29 into the printed circuit board 22.

The pins 28 are integrated into the pin carrier 50. A single pin carrier 50 can support all the pins 28. The pins 28 extend from the top and bottom of the pin carrier 50, and the ends 27 and 29 of the pins 28 are free. The pin carrier 50 includes, for example, a body 36 molded around each pin 28, or the pins 28 can be introduced by force through the body 36 of the pin carrier 50. The pin carrier 50 in particular allows the pins 28 to be fixed relative to the housing 20. The body 36 of the pin carrier 50 cooperates with the connector receptacle 32 to immobilize the pins 28 and thus to immobilize the printed circuit board 22 relative to the housing 20. In particular, the pin carrier 50 can cooperate with the base of the connector receptacle 32 that opens into the housing 20. The pin carrier 50 can include a shoulder 37 that cooperates with a raised edge in the connector receptacle 32. Moreover, the pin carrier 50 can also seal the housing 20. The pin carrier 50 can be designed, particularly as regards its shoulder 37, to block the through hole of the pins 28 between the connector receptacle 32 and the inside of the housing 20. Moreover, the pin carrier 50 can be fitted with an annular seal 51 on the body 36 to seal the housing 20. The annular seal 51 can cooperate with the connector receptacle 32 to seal the housing 20.

A problem arises in the assembly of such a geared motor 10. Because the pins 28 are able to be connected directly to the control connector, they are longer than standard pins. The pins 28 are attached to the printed circuit board 22 and can be introduced into the housing 20 with the printed circuit board 22 through the interface 21 of the housing 20. In this case, the pins 28 abut against the housing 20.

Thus, one method of assembling the geared motor 10 includes the step of fitting the pins 28 in the geared motor 10 independently of the printed circuit board 22. A first step includes providing the housing 20, the printed circuit board 22 and the pins 28. The pins 28 and the printed circuit board 22 are not assembled. The method then involves the step of inserting the printed circuit board 22 into the housing 20. The printed circuit board 22 can be introduced into the housing 20 substantially along the axis of the rotor 14. The housing 20 can have slots or grooves to receive the printed circuit board 22. The printed circuit board 22 can be introduced into the housing 20 until it is fully home against the back of the housing 20. The method can then involve steps of introducing the pins 28 into the connector receptacle 32 and bringing the pins 28 into contact with the printed circuit board 22. The pin carrier 50 is introduced through the connector receptacle 32 until the pins 28 make contact with the printed circuit board 22. The connector receptacle 32 therefore allows the pins 28 to be fitted into the geared motor 10 even when the pins 28 are longer. This assembly solution allows the printed circuit board 22 to be inserted into the housing 20 without a specific arrangement of the interface 21. The housing 20 can therefore have the member forming the interface 21 and elements for attachment to the motor which are standard and thus less costly.

For example, the pins 28 can easily be brought into contact with the printed circuit board 22 by introducing the end 29 of the pins 28 into the printed circuit board 22 by force. The pins 28 fitted to the pin carrier 50 can also be introduced into the connector receptacle 32. This immobilizes the pins 28 and the printed circuit board 22 and seals the housing 20. This seal can be reinforced by fitting the annular seal 51 on the body 36.

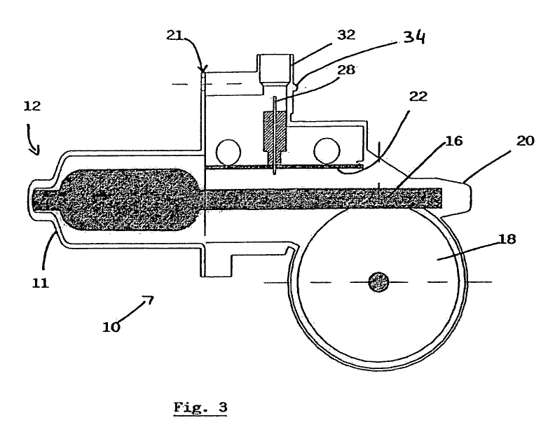

FIG. 3 shows another embodiment of the geared motor 10. As in FIG. 1, the geared motor 10 includes the housing 20 attached to the stator 11. The housing 20 has the interface member 21 for attachment to the stator 11. The geared motor 10 also includes the reduction gear composed of the worm screw 16 on the rotor 14 and the cog wheel 18 driven by the worm screw 16. The printed circuit board 22 is also shown with the same specific characteristics as in FIG. 1.

The geared motor 10 also includes the printed circuit board 22 and the connector receptacle 32. The printed circuit board 22 is positioned and has the characteristics mentioned above. Like that of FIG. 1, the connector receptacle 32 of FIG. 3 allows a geared motor control connector to be attached to the geared motor 10. The connector receptacle 32 projects from the housing 20, enabling it directly to receive the connector. The connector receptacle 32 is also designed to serve as an adapter. The advantages associated with the connector receptacle 32 are the same as those mentioned previously. In particular, such a geared motor 10 avoids the use of an adapter for integrating the connector into the geared motor 10, reducing the production costs of the geared motor 10. Moreover, to avoid the use of the adapter, the pins 28 are longer as in FIGS. 1 and 2. The pins 28 can be of the same size as those shown in the other figures.

The geared motor 10 of FIG. 3 differs from that of the other two figures in that the motor-attachment interface 21 has a larger opening for the rotor 14 of the motor 14 to pass through. The opening terminates at an upper portion of the connector receptacle 32 in the direction in which the rotor 14 passes through. In other words, part of the opening through the interface 21 is larger in a crosswise direction to the direction of the rotor 14 in the plane of the figure. The opening through the interface member is increased by the size of the pins 28. The distance between the axis of the rotor 14 and the top of the housing 20 is greater than the distance between the axis of the rotor 14 and the top of the pins 28. The motor-attachment interface 21 therefore has a larger surface area. Thus, it would be possible to introduce longer pins 28 through the interface opening, provided that the pins 28 have been attached to the printed circuit board 22 beforehand.

The housing 20 is shaped between the opening of the interface 21 and the connector receptacle 32 to enable the pins 28 to pass through. In the direction of the rotor 14, the connector receptacle 32 has a wall opposite the interface 21 which projects beyond the rest of the housing 20. The wall of the connector receptacle 32 supports the attachment element 34. Also in the direction of the rotor 14, the connector receptacle 32 has another wall partially blended into the housing 20. Thus, the perimeter of the housing 20 between the interface 21 and the connector receptacle 32 is increased.

The motor 12 is attached to the interface 21 by the stator 11. Because the interface 21 has a larger surface area, the stator 11 of the motor 12 is shaped to match the interface 21. In FIG. 3, the stator 11 has a wall which matches the shape of the interface 21.

As the pins 28 are larger to allow connection without an adapter, another method of assembling the geared motor in FIG. 3 may be adopted. This method also solves the problem of introducing longer pins 28 into the housing 20. The method of assembling the geared motor 10 includes the step of fitting the pins 28 in the printed circuit board 22 before introducing the printed circuit board 22 into the geared motor 10. Due to the space made available by increasing the height of the housing 20 emerging into the connector receptacle 32, it is possible to insert the printed circuit board 22 fitted with its pins 28.

A first step includes providing the housing 20 as described in relation to FIG. 3, the printed circuit board 22 and the pins 28. The pins 28 and the printed circuit board 22 are then assembled. To do this, the pins 28 are, for example, soldered to the printed circuit board 22. The pins 28 can extend in a direction perpendicular to the plane of the printed circuit board 22 (when the pins 28 are inserted through the printed circuit board 22) or be bent parallel to the printed circuit board 22 and soldered on the surface without inserting the pins 28 through the printed circuit board 22. The method then includes a step of introducing the printed circuit board 22 into the housing 20. Introduction into the housing 20 can be carried out in the direction in which the rotor 14 passes through, making it easier to introduce the printed circuit board 22. Moreover, since the housing 20 is shaped to increase its perimeter and allow the pins 28 to pass through, it is easier to introduce the printed circuit board 22 equipped with its pins 28. This method has the advantage of enabling the printed circuit board 22 and the pins 28 to be fitted into the geared motor 10 at the same time, which makes it easier to assemble the geared motor 10.

The methods described above can then involve steps to complete assembly of the geared motor 10, such as introducing the rotor 14 into the housing 20, parallel to the printed circuit board 22, and attaching the motor 12 to the housing 20, for example at the interface 21 of the housing 20.

The foregoing description is only exemplary of the principles of the invention. Many modifications and variations are possible in light of the above teachings. It is, therefore, to be understood that within the scope of the appended claims, the invention may be practiced otherwise than using the example embodiments which have been specifically described. For that reason the following claims should be studied to determine the true scope and content of this invention.

What is claimed is:

1. A geared motor comprising
a motor including a rotor and a stator;
a housing fixed to the motor;
a connector receptacle integrated into and projecting from the housing, wherein a control connector for controlling the geared motor is directly receivable in the housing;
a printed circuit board for controlling operation of the geared motor, wherein the printed circuit board is within the housing and extends in a common direction to an axis of the rotor; and
conducting pins connected to the printed circuit board that are directly connectable to the control connector.

2. The geared motor according to claim 1, wherein the connector receptacle comprises at least one element for securing the control connector to the connector receptacle.

3. The geared motor according to claim 1, wherein the conducting pins include a free end and the connector receptacle includes an upper portion, and the conducting pins are attached to the printed circuit board and the free end of the conducting pins are in the upper portion of the connector receptacle.

4. The geared motor according to claim 1, wherein the housing includes a member forming an interface for attaching the motor, the member includes an opening for the rotor to pass through and the connector receptacle includes an upper portion, wherein the opening is defined by the upper portion of the connector receptacle.

5. The geared motor according to claim 4, wherein the housing includes a housing top and the conducting pins each include a pin top, wherein a distance between the axis of the rotor and the housing top of the housing is greater than a distance between the axis of the rotor and the pin top of the conducting pins.

6. The geared motor according to claim 1, wherein the conducting pins immobilize the printed circuit board relative to the housing.

7. The geared motor according to claim 6, wherein the conducting pins include a pin carrier for attachment to the housing.

8. A method for assembling a geared motor including a motor with a rotor and a stator, a housing fixed to the motor, a connector receptacle integrated into and projecting from the housing, wherein a control connector for controlling the geared motor is directly receivable in the housing, a printed circuit board for controlling operation of the geared motor that is within the housing extends in a common direction to an axis of the rotor, and conducting pins are connected to the printed circuit board and directly connectable to the control connector for the geared motor, wherein the conducting pins immobilize the printed circuit board relative to the housing, the method comprising the steps of:
introducing the printed circuit board into the housing;
introducing the conducting pins through an opening of the connector receptacle; and
establishing a connection between the conducting pins and the printed circuit board.

9. The method according to claim 8, wherein the conducting pins comprise a pin carrier, and the method further comprises a step of attaching the pin carrier to the housing.

10. The method according to claim 8, wherein the step of introducing the printed circuit board includes introducing the printed circuit board in a direction of introduction, and the conducting pins extend in a direction substantially perpendicular to the direction of introduction.

11. The method according to claim 8, wherein the housing includes a member that forms an interface for attaching the motor, the member includes an opening for the rotor to pass through and the printed circuit board is introduced into the housing in the common direction to the axis of the rotor.

12. A method for assembling a geared motor including a motor with a rotor and a stator, a housing fixed to the motor, a connector receptacle including an upper portion integrated into and projecting from the housing, wherein a control connector for controlling the geared motor is directly receivable in the housing, a printed circuit board for controlling operation of the geared motor that is within the housing extends in a common direction to an axis of the rotor, and conducting pins are connected to the printed circuit board and directly connectable to the control connector, wherein the housing includes a member forming an interface for attaching the motor, and the member includes an opening for the rotor to pass through that is defined by the upper portion of the connector receptacle, the method comprising the steps of:
securing the conducting pins to the printed circuit board; and
introducing the printed circuit board through the opening of the housing in the common direction to the axis of the rotor.

13. The assembly method according to claim 12, wherein the housing includes a housing top and the conducting pins each include a pin top, wherein a distance between the axis of the rotor and the housing top of the housing is greater than a distance between the axis of the rotor and the pin top of the conducting pins.
